(19) United States
(12) Patent Application Publication
(10) Pub. No.: US 2025/0353134 A1
(43) Pub. Date: Nov. 20, 2025

(54) HEAT CLEANING SYSTEM AND METHOD FOR CMP PAD BY-PRODUCT CONTROL

(71) Applicant: Taiwan Semiconductor Manufacturing Company, Ltd., Hsinchu (TW)

(72) Inventors: Chi-hsiang Shen, Tainan (TW); Te-Chien Hou, Kaohsiung (TW); Jeng-Chi Lin, Hsinchu (TW)

(73) Assignee: Taiwan Semiconductor Manufacturing Company, Ltd., Hsinchu (TW)

(21) Appl. No.: 18/663,606

(22) Filed: May 14, 2024

(51) Int. Cl. B24B 37/015; B24B 37/04; B24B 53/017; H01L 21/321

(52) U.S. Cl. CPC B24B 37/015; B24B 37/042; B24B 53/017; H01L 21/3212

(57) ABSTRACT

A semiconductor planarization method includes: commencing rinsing a polishing pad surface for polishing a wafer surface with a pad rinsing solution including deionized water and a chemical chelator configured to capture metal by-products from chemical mechanical planarization (CMP) operations; determining a by-product concentration from runoff from the pad rinsing solution; heating the pad rinsing solution while continuing to rinse the polishing pad surface when the by-product concentration is above a first by-product threshold level; ceasing to heat the pad rinsing solution when the by-product concentration is below a second by-product threshold level; and ceasing rinsing the polishing pad surface.

### BACKGROUND

Chemical mechanical planarization (CMP) is widely used in the fabrication of integrated circuits. As an integrated circuit is built layer by layer on a surface of a semiconductor wafer, CMP processes are used to planarize the topmost layer or layers to provide a leveled surface for subsequent fabrication operations. CMP processes are carried out by placing the semiconductor wafer in a wafer carrier that presses the wafer surface to be polished against a polishing pad attached to a platen. Both the platen and the wafer carrier are rotated while an abrasive slurry containing both abrasive particles and reactive chemicals is applied to the polishing pad. The slurry is transported to the wafer surface via the rotation of the polishing pad. The relative movement of the polishing pad and the wafer surface coupled with the reactive chemicals in the abrasive slurry allows the CMP process to level the wafer surface by both physical and chemical forces. CMP is an effective way to achieve global wafer planarization for advanced integrated circuits.

CMP can be used at a number of points during the fabrication of an integrated circuit. For example, CMP can be used to planarize the inter-level dielectric layers that separate the various circuit layers in an integrated circuit. CMP can also be commonly used in the formation of the metal lines that interconnect components of an integrated circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an isometric view of a Chemical Mechanical Planarization (CMP) system, according to various embodiments.

FIG. 2 is an isometric view of selected components of an exemplary CMP polisher, according to various embodiments.

FIG. 3 is a block diagram depicting a cleaning system for use with a CMP polisher, according to various embodiments.

FIG. 4A is a block diagram depicting example components of a measurement system of a cleaning system used with a CMP polisher, according to various embodiments.

FIG. 4B is a block diagram depicting example components of a heat system and a measurement system of a cleaning system used with a CMP polisher, according to various embodiments.

FIG. 5A is a block diagram illustrating an example particle counter, according to various embodiments.

FIG. 5B is a block diagram illustrating operations of an example heat control system, according to various embodiments.

FIG. 6A is a graph that illustrates an example relationship between zeta potential and temperature, according to various embodiments.

FIG. 6B is a graph that illustrates an example relationship between mean particle size and temperature, according to various embodiments.

FIG. 7 is a plot that indicates particle counts of the by-product that can be achieved when rinsing the abrasive pad with a non-heated pad rinsing solution such as DI water versus rinsing the abrasive pad with a heated pad rinsing solution, according to various embodiments.

FIG. 8 is a process flow chart depicting an example process for semiconductor planarization, according to various embodiments.

FIG. 9 is a process flow chart depicting an example process for semiconductor planarization, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer, or section from another. The terms such as “first,” “second” and “third” when used herein do not imply a sequence or order unless clearly indicated by the context.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

The term “nominal” as used herein refers to a desired or target value, and values above and/or below the desired value, of a characteristic or parameter of a component or process operation set during the design phase of a product or process. The range of values is typically due to minor variations in manufacturing processes or tolerances.

The term “substantially” as used herein means a value of a given quantity that may vary based on the particular technology node associated with the semiconductor element. In some embodiments, the term “substantially” may represent a value of a given amount that varies, for example, within +5% of a target (or expected) value, based on a particular technology node.

The term “about (about)” as used herein denotes a value of a given amount that may vary based on the particular technology node associated with the subject semiconductor element. In some embodiments, the term “about” may represent a value of a given amount that varies, for example, within 5% to 30% of the value (e.g., ±5% of the value, ±10% of the value, ±20%, or ±30% of the value), based on the particular technology node.

The term “vertical” as used herein refers to a surface that is nominally perpendicular to the substrate.

It is to be understood that the phraseology or terminology herein is for the purpose of description and not of limitation, such that the terminology or phraseology of the present specification is to be interpreted by those skilled in relevant art(s) in light of the teachings herein.

Integrated circuits contain numerous devices such as transistors, diodes, capacitors, and resistors that are fabricated on and/or in a semiconductor substrate. These devices are initially isolated from one another and are later interconnected to form functional circuits. As device densities in integrated circuits increase, multiple wiring levels are required to achieve interconnections of these devices. CMP processes are commonly used in the formation of multilevel interconnect structures.

In a multilevel interconnect structure, conductive lines (e.g., copper lines) are laid in stacked dielectric layers and are connected through vias from one layer to another layer. The conductive lines and vias are fabricated using single or dual damascene processes in some instances. In such processes, a dielectric layer is patterned to form contact openings including trenches and/or via openings. A barrier layer is deposited along sidewalls and bottom surfaces of the contact openings, followed by depositing a conductive layer over the barrier layer to overfill the contact openings. A CMP process is then performed to remove the overlying conductive layer and barrier layer from the surface of the dielectric layer, thus forming isolated conductive contacts.

Chemical Mechanical Planarization (CMP) is a wafer surface planarization technique that planarizes a wafer surface by relative motion between a wafer and a polishing pad in the presence of slurry while applying pressure (downforce) to the wafer. CMP tools are considered “grinders”. In a grinder, the wafer is placed face down on a wafer support or carrier. The opposing wafer surface holds the polishing pad against a flat surface, which is referred to as a “platen”. The grinding machine may use a rotary or orbital motion during the grinding process. CMP achieves planarity of the wafer by removing raised features of the wafer surface relative to recessed features.

Slurries are mixtures of fine abrasive particles and chemicals used to remove certain materials from the wafer surface during a CMP process. Accurate slurry mixing and consistent batch mixing are important to achieving wafer to wafer (WtW) and lot to lot (lot to lot; LtL) polishing repeatability (e.g., consistent polishing rate, consistent polishing uniformity across wafer and die, etc.). The quality of the slurry is important so that scratches on the wafer surface can be prevented during the CMP process.

An abrasive pad is attached to the top surface of the platen. The polishing pad may be made of, for example, polyurethane (polyurethane), based on the mechanical properties and porosity of polyurethane. Further, the polishing pad may have small perforations (e.g., grooves) to help transport slurry along the surface of the wafer and to promote uniform polishing. The polishing pad also removes the products of the reaction from the surface of the wafer.

By-products from CMP operations, however, can gradually accumulate on polishing pads, which can shorten pad life, affect machine efficiency, and increase production costs. Pad cleaning chemicals may be used to refresh polishing pads, extend pad life, and reduce wafer defects. But, even with pad cleaning chemicals, wafers per hour (WPH) throughput, cleaning efficiency, and raw material cleaning cost may increase the longer polishing pads are used.

Apparatus, systems, operations, and techniques disclosed herein describe a novel cleaning system that can improve polishing pad cleaning, reduce CMP induced defects, and extend the life of polishing pads. In various embodiments, a novel heating system is disclosed for improving polishing pad cleaning. In various embodiments, real-time measurement of large particle count (LPC) can be made to determine when to enable the novel heating system. In various embodiments, a LPC counter is implemented to measure LPC. In various embodiments, zeta potential can be utilized to control the LPC of polishing pad by-products. In various embodiments, traditional inefficient and expensive pad cleaning chemicals can be replaced by a pad rinsing solution that can be selectively heated.

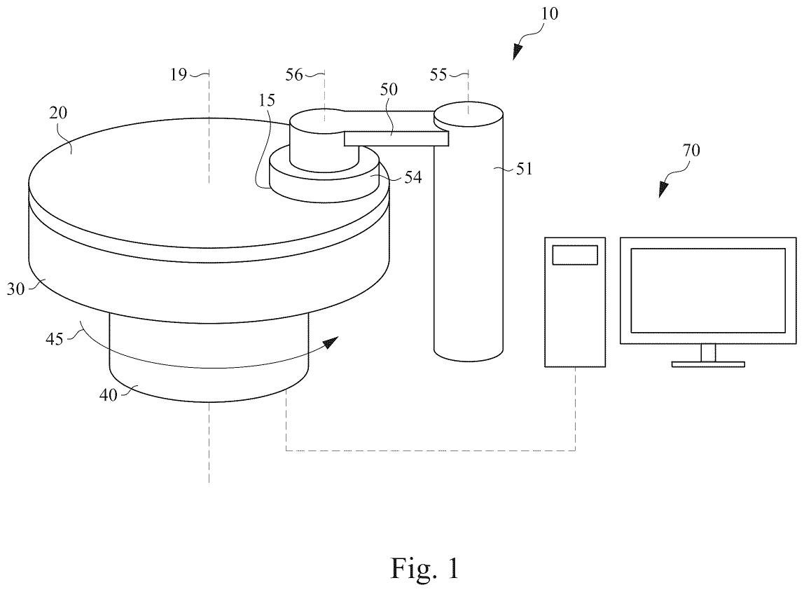

FIG. 1 is an isometric view of an example Chemical Mechanical Planarization (CMP) system 10, in accordance with some embodiments. The example CMP system 10 is configured for performing a CMP process on a wafer 15 in a semiconductor manufacturing process.

In certain embodiments, the CMP system 10 includes a polishing pad 20, a platen 30, a platen motor 40, a wafer holder assembly 50 and a controller 70. The elements of the CMP system 10 can be added to or omitted, and the disclosure should not be limited by the embodiments. For example, in certain embodiments the CMP system 10 may include an atomizer, a slurry dispenser, and a conditioning assembly.

The platen 30 is configured to receive and rotate the polishing pad 20 about a center axis 19. In some embodiments, the platen 30 is circular in shape. The diameter of the platen 30 lies in a range that is substantially larger than the diameter of the wafer 15 to be polished.

The platen motor 40 rotates the platen 30 in the direction of arrow 45 about the axis 19. As shown, the platen motor 40 is electrically connected to the controller 70 and may be actuated and operated by the controller 70.

In certain embodiments, the polishing pad 20 is fixed onto the platen 30. The polishing pad 20 may be a consumable item used in a semiconductor wafer fabrication process. In certain embodiments, the polishing pad 20 may be a hard, incompressible pad or a soft pad. For oxide polishing, hard and stiffer pads are generally used to achieve planarity. Softer pads are generally used in other polishing processes to achieve improved uniformity and a smooth surface. The hard pads and the soft pads may also be combined in an arrangement of stacked pads for customized applications.

The wafer holder assembly 50 is used to support the wafer 15. In some embodiments, the wafer holder assembly 50 includes a shaft 51 with a driving motor, and a carrier head 54. The driving motor may be configured to control the movement of the carrier head 54 about a rotation axis 55. In some embodiments, the driving motor is an electric motor which converts electrical energy into mechanical energy for driving the rotation of the shaft 51. In some embodiments, the shaft 51 is driven to be rotatable about the rotation axis 55 by an external force (e.g., frictional force generated between the polishing pad 20 and the wafer 15) that is applied to the shaft 51 no matter which operation state of the driving motor.

In some embodiments, the carrier head 54 is rotatable about a rotation axis 56 by another driving motor (not shown in figures). The rotation axis 56 is different from the rotation axis 55.

The carrier head 54 may include a retainer retaining ring having an annular shape and a hollow center. The wafer 15 may be placed in the hollow center of retaining ring during the CMP process.

In one or more examples, the controller 70 includes or may be implemented in a computer including hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a computer).

Instructions may be configurable to be executed by one or more processors, such as one or more digital signal processors (DSPs), general purpose microprocessors, application specific integrated circuits (ASICs), field programmable logic arrays (FPGAs), or other equivalent integrated or discrete logic circuitry, included in controller 70. Accordingly, the term “processor” as used herein may refer to any of the foregoing structure or any other physical structure suitable for implementation of the described techniques. Also, the techniques could be fully implemented in one or more circuits or logic elements.

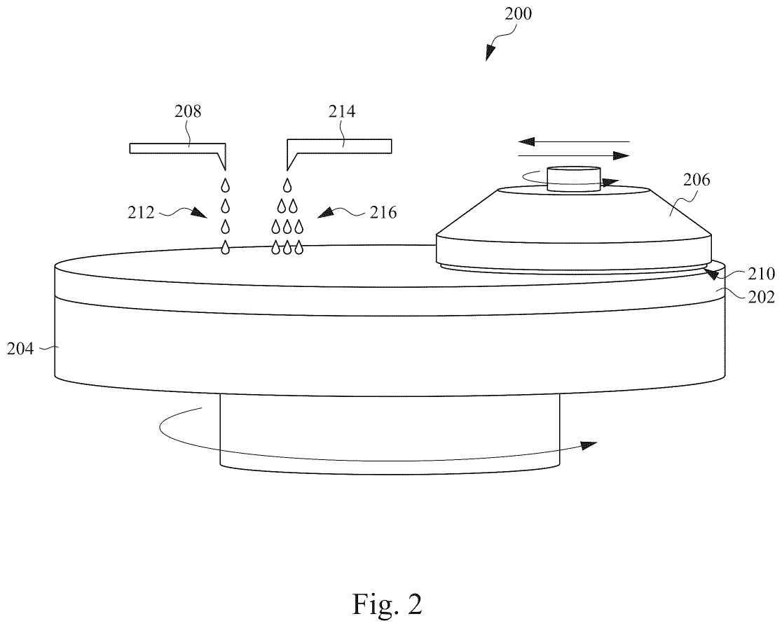

FIG. 2 is an isometric view of selected components of an exemplary CMP polisher 200 (also referred to as a grinder) according to some embodiments. The polisher 200 includes a polishing pad 202 (also referred to as a grinding pad), the polishing pad 202 being mounted on a rotating platen (e.g., a rotating table) 204. The polisher 200 also includes a rotating wafer carrier 206 and a slurry feeder 208. For illustrative purposes, FIG. 2 includes selected portions of the polisher 200, and may include other portions (not shown), such as chemical delivery lines, discharge lines, control units, transfer modules, pumps, and the like. A wafer 210 to be ground is mounted face down (e.g., with its top surface facing down) on the bottom of the wafer carrier 206 such that the top surface of the wafer contacts the top surface of the pad 202. The wafer carrier 206 rotates the wafer 210 and applies pressure (e.g., a down force) to the wafer 210 so that the wafer 210 is pressed against the rotating pad 202. A slurry 212 comprising chemicals and abrasive particles is dispensed on the surface of the polishing pad 202. Chemical reactions and mechanical wear between the slurry 212, the wafer 210, and the pad 202 may result in material being removed from the top surface of the wafer 210.

In some embodiments, the platen 204 and the wafer carrier 206 rotate in the same direction (e.g., clockwise or counterclockwise) but with different angular velocities (e.g., rotational velocities). At the same time, the wafer carrier 206 may oscillate between the center and the edge of the pad 202. However, the above-described relative movement of the various rotating components (e.g., the wafer carrier 206 and the platen 204) is not limiting.

In some embodiments, the physical and mechanical properties of the pad 202 (e.g., roughness, material selection, porosity, stiffness, etc.) depend on the material to be removed from the wafer 210. For example, copper polishing, copper barrier polishing, tungsten polishing, shallow trench isolation polishing, oxide polishing and buffer polishing (buff polishing), which require different types of polishing pads in terms of material, porosity, and stiffness. The polishing pad used in a polishing machine (e.g., polisher 200) should have a certain rigidity in order to uniformly polish the surface of the wafer. The polishing pad (e.g., pad 202) may be a stack of soft and hard materials that may conform to some degree to the local topography of the wafer 210. By way of example and not limitation, the pad 202 may comprise a porous polymeric material having a pore size between about 1 micrometer (μm) and about 500 micrometers.

Further, the polisher 200 is provided with a pad rinsing nozzle 214 for dispensing a pad rinsing solution 216 comprising pressurized deionized (DI) water and/or other chemicals (e.g., chemical chelator) onto the surface of the polishing pad 202 to clean the polishing pad 202 before and/or after CMP operations. In some embodiments, cleaning the polishing pad 202 may be performed while the polishing pad 202 is rotating or while the polishing pad 202 is stationary. In other embodiments, cleaning the polishing pad 202 may be performed using more than one pad rinsing nozzle 214. For example, a plurality of pad rinsing nozzles 214 may be disposed around and/or over the polishing pad 202. In some embodiments, cleaning the polishing pad 202 removes by-products (e.g., slurry or other abrasive material from wafer 210) generated during a CMP process from the surface of the polishing pad 202.

In various embodiments, the chemical chelator comprises a chemical compound that reacts with metal ions to form a stable, water-soluble complex. In various embodiments, the chemical chelator is configured to capture metal by-products from CMP operations. In various embodiments, the chemical chelator has a kinetic energy level wherein the kinetic energy level of the chemical chelator increases as the temperature of the pad rinsing solution increases and wherein an increased chemical chelator kinetic energy level enables the chemical chelator to grab an increased concentration of particle by-products. In various embodiments, the chemical chelator comprises a sulfonyl hydroxide, hydroxide or phosphate radical. The chemical chelator can replace expensive pad cleaning chemicals and save on process costs.

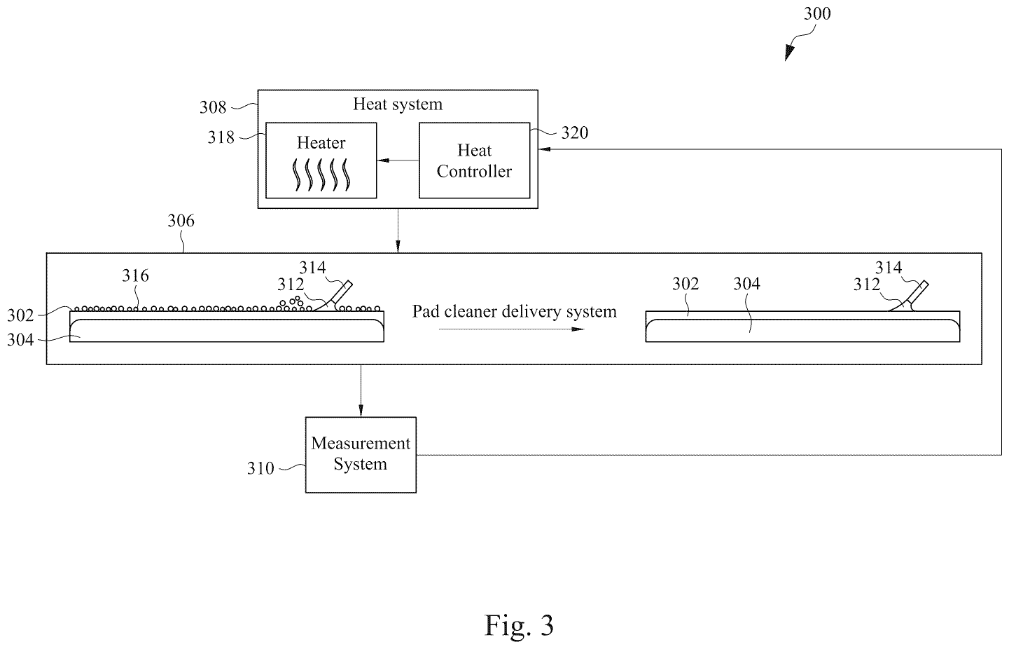

FIG. 3 is a block diagram depicting an example cleaning system 300 for use with a CMP polisher (such as CMP polisher 200). The cleaning system 300 is configured to clean a surface 302 of an abrasive polishing pad 304 of the CMP polisher before and/or after CMP polishing operations. The cleaning system 300 includes a heat system 308 for selectively delivering heat to the pad cleaner delivery system 306, and a measurement system 310. The pad cleaner delivery system 306 includes a pad rinsing nozzle 314 for delivering pad rinsing solution 312 to the abrasive polishing pad 304 to clean the abrasive polishing pad 304 by removing by-products 316 from the surface 302 of the abrasive polishing pad 304. The heat system includes a heat source 318 for selectively providing heat to a heat transfer element, the heat transfer element (not shown) for transferring heat, when needed, without contact to pad rinsing solution 312, and a heat controller 320 for selecting when and/or how much heat from the heat source 318 to provide to the heat transfer element. In various embodiments, the heat controller 320 comprises one or more processors configured by programming instructions on non-transitory computer readable media. The measurement system 310 includes a particle detection system (not shown) for detecting the concentration of particles washed away from the polishing pad in runoff, a temperature measurement device (not shown) for measuring the temperature of the pad rinsing solution 312 when exiting the pad rinsing nozzle 314, and a zeta potential measurement unit for measuring the zeta potential of the pad rinsing solution 312. The heat system 308 uses measurements from the measurement system 310 to determine how much heat to provide to the heat transfer element.

The cleaning system 300 can replace expensive pad cleaning chemicals with a chemical chelator and save on process costs. The cleaning system 300 can achieve self-pad cleaning (via hot DI water or hot slurry) without risk of cross-contamination of different vendor slurry. The cleaning system 300 can control the amount of pad by-products to reduce defects without over cleaning the pad, whereas over cleaning the pad can reduce pad life by increasing chemical corrosion of the pad.

In some embodiments, the heat system begins to heat the pad rinsing solution 312 applied to the abrasive pad 304 by a pad rinsing nozzle 314 when the particle count from by-products 316 removed from the surface 302 of the abrasive pad 304 is higher than a first threshold level. In these embodiments, when the particle count from by-products 316 removed from the surface 302 of the abrasive pad 304 falls lower than a second threshold level, the heat system ceases heating the pad rinsing solution 312 applied to the abrasive pad 304 by a pad rinsing nozzle 314. In some embodiments the first threshold level is substantially equal to the second threshold level. In other embodiments the first threshold level is substantially higher than the second threshold level.

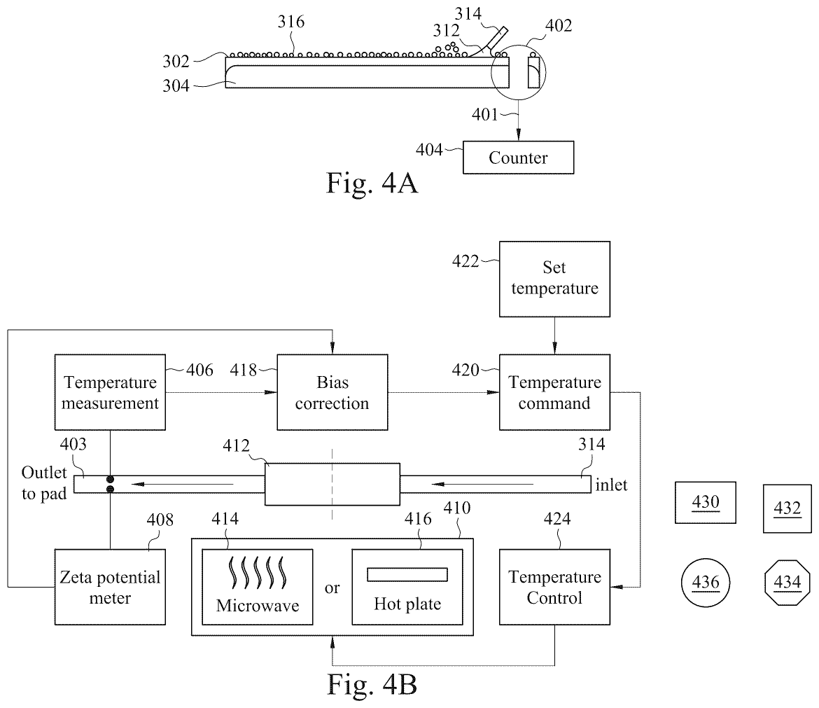

FIG. 4A is a block diagram depicting example components of a measurement system 310 of a cleaning system 300 used with a CMP polisher (such as CMP polisher 200). FIG. 4B is a block diagram depicting example components of a heat system 308 and a measurement system 310 of a cleaning system 300 used with a CMP polisher.

The example components of the measurement system include a drain hole 402 in the abrasive pad 304 (and underlying platen) for allowing at least some runoff 401 (e.g., pad rinsing solution 312 containing particles from by-products 316 that is removed from the surface 302 of the pad 304) from rinsing the polishing pad surface to drain, a particle counter 404 for measuring particle count from at least some of the runoff 401 (pad rinsing solution 312 and by-products 316 removed from the surface 302 of the abrasive pad 304), a temperature measurement device 406 configured to estimate the temperature of the pad rinsing solution 312 at or near an outlet 403 of the pad rinsing nozzle 314, and a zeta potential device 408 (e.g., meter) for estimating the zeta potential of the pad rinsing solution 312 at or near the near the outlet 403 of the pad rinsing nozzle 314. In various embodiments, the length of the drain hole 402 can be 10 mm to approximately 25 mm. In various embodiments, the particle by-products comprise particles greater than a predetermined size (e.g., 10 nm˜5000 nm).

In various embodiments, the temperature measurement device 406 uses an infrared sensor to measure temperature. In various embodiments, the temperature measurement device 406 comprises a valve configured to open when the pad rinsing solution temperature at or near the outlet of the polishing pad rinsing nozzle is estimated to be at or above a first temperature threshold level and configured to close when the pad rinsing solution temperature at or near the outlet of the polishing pad rinsing nozzle is estimated to be below the second temperature threshold level. In various embodiments, the first temperature threshold level is substantially higher than the second temperature threshold. In various embodiments, the first temperature threshold level is substantially equal to the second temperature threshold.

The example components of the heat system includes a heat source 410 for generating heat, a heat transfer structure 412 configured to transfer heat from the heat source 410 to the to the pad rinsing solution 312, and a heat controller configured to determine when to apply the heat from the heat source 410 to the pad rinsing solution 312. In various embodiments, the heat source 410 comprises a microwave heating device 414 for applying heat to the pad rinsing solution 312. In various embodiments, the heat source 410 comprises a hot plate 416 for applying heat to the pad rinsing solution 312. In various embodiments, the heat system source can be used to heat slurry used in grinding the wafer.

In various embodiments, the heat transfer structure 412 comprises a quartz structure wrapped around at least a portion of the polishing pad rinsing nozzle. In various embodiments, the heat transfer structure 412 comprises a ceramic structure wrapped around at least a portion of the polishing pad rinsing nozzle. In various embodiments, the heat transfer structure 412 comprises a bendable tube-like spring structure. In various embodiments, the heat transfer structure 412 comprises a non-bendable pipe structure. In various embodiments, the heat transfer structure 412 has a rectangular 430, square 432, polygonal 434, or circular 436 cross-sectional shape (as measured at cut-line 1-1′) around the pad rinsing nozzle 314.

In various embodiments, the heat controller comprises one or more processors configured by programming instructions on non-transitory computer readable media. In various embodiments, the heat controller is configured to begin applying the heat from the heat source to the pad rinsing solution when the concentration of particle by-products in the runoff is above a first particle threshold level, and cease applying heat from the heat source when the concentration of particle by-products in the runoff is below a second particle threshold level.

In various embodiments, the heat controller is configured to determine how much of the heat from the heat source to apply to the pad rinsing solution based on a pad rinsing solution temperature. In various embodiments, when the LPC is high, the magnitude of the zeta potential, as measured by the zeta potential device 408, can be increased by increasing the pad rinsing solution temperature. In various embodiments, the pad rinsing solution temperature is estimated using the temperature measurement device 406. In various embodiments, the heat controller is configured to control the temperature of the pad rinsing solution 312 between room temperature and 90° C. by controlling the amount of heat applied to the heat transfer structure 412, e.g., by turning on or off the heat source 410.

In various embodiments, the heat controller is configured to provide bias correction 418 to regulate an amount of heat to apply to the pad rinsing solution 312 based on the pad rinsing solution temperature estimated from the temperature measurement device 406.

In various embodiments, the heat controller is configured to provide a temperature command 420 directed to the heat source 410 based on a set temperature 422 (fixed or programmable) and the bias correction 418.

In various embodiments, the heat controller further comprises a temperature controller 424 configured to translate the temperature command 420 into commands for controlling the heat source 410. In various embodiments, the temperature controller 424 comprises one or more processors configured by programming instructions on non-transitory computer readable media.

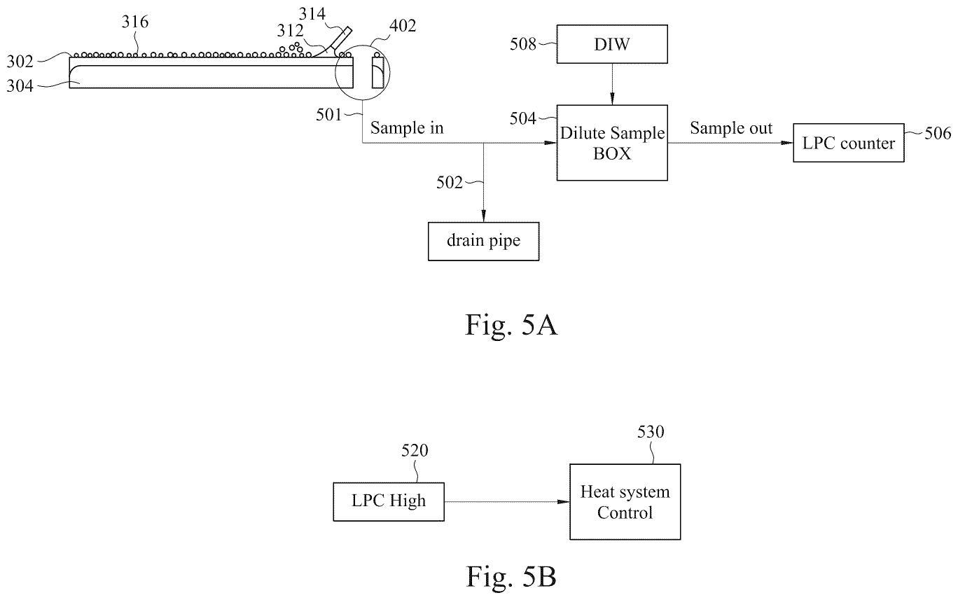

FIG. 5A is a block diagram illustrating an example particle counter 404. The example particle counter 404 includes a drain pipe 502, a dilute sample box 504, and a large particle count (LPC) counter, wherein the dilute sample box 504 is configured to collect at least a portion of the runoff 501 and deionized water 508 used to dilute the runoff 501, the drain pipe 502 is provided to release excess from the deionized water 508 and the runoff 501 that is not collected in the dilute sample box 504, and the LPC 506 counter is configured to estimate the count of large particles in the dilute sample box 504.

FIG. 5B is a block diagram illustrating operations of an example heat control system. When the particle count is higher than a threshold level as determined by the example particle counter 404 (operation 520), the heat control system begins heating pad rinsing solution (operation 530).

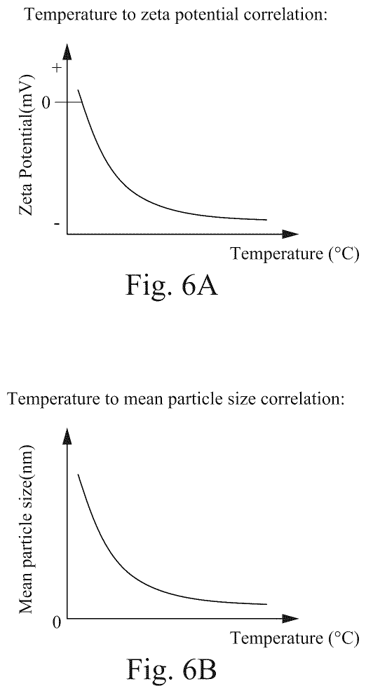

FIG. 6A is a graph that illustrates an example relationship between zeta potential and temperature. As the temperature rises, the magnitude of the zeta potential rises. In various embodiments, the relationship can be expressed as a multiplicative inverse function. Measurement of the temperature of the pad rinsing solution can be an indicator of the zeta potential.

FIG. 6B is a graph that illustrates an example relationship between mean particle size and temperature. As the temperature rises, the particle size of by-products falls. In various embodiments, the relationship can be expressed as a multiplicative inverse function. Measurement of the particle size can be an indicator of the temperature of the pad rinsing solution.

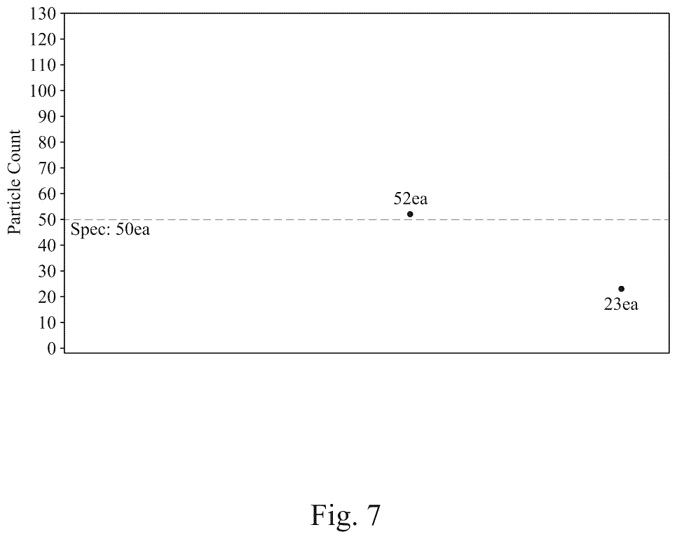

FIG. 7 is a plot that indicates particle counts of the by-product that can be achieved when rinsing the abrasive pad with a non-heated pad rinsing solution such as DI water versus rinsing the abrasive pad with a heated pad rinsing solution 312. In this example, a particle count of 52 was achieved by rinsing the abrasive pad with a non-heated pad rinsing solution, whereas a particle count of 23 was achieved by rinsing the abrasive pad with a heated pad rinsing solution 312. In this example, an improvement of approximately 55% was achieved.

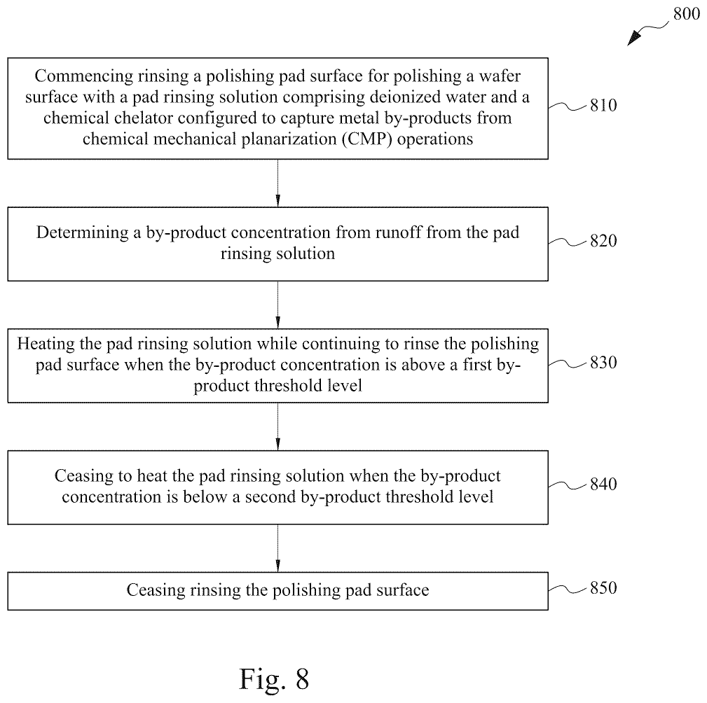

FIG. 8 is a process flow chart depicting an example process 800 for semiconductor planarization. The process 800 is merely an example, and is not intended to limit the present disclosure beyond what is explicitly recited in the claims. Additional steps may be provided before, during, and after example process 800, and some of the steps described can be moved, replaced, or eliminated for additional embodiments of example process 800.

At step 810, process 800 includes commencing rinsing a polishing pad surface for polishing a wafer surface with a pad rinsing solution comprising deionized water and a chemical chelator configured to capture metal by-products from chemical mechanical planarization (CMP) operations. In various embodiments, commencing rinsing the polishing pad surface is performed before the wafer surface is polished using CMP operations. In various embodiments, commencing rinsing the polishing pad surface is performed after the wafer surface is polished using CMP operations.

At step 820, process 800 includes determining a by-product concentration from runoff from the pad rinsing solution. In various embodiments, determining the by-product concentration from the runoff comprises measuring the by-product concentration in the runoff from rinsing the polishing pad surface using a particle counter. In various embodiments, the particle counter comprises a drain pipe, a dilute sample box, and a large particle count (LPC) counter, wherein the dilute sample box is configured to collect at least a portion of the runoff and deionized water used to dilute the runoff, the drain pipe is provided to release excess from the deionized water and the runoff that is not collected in the dilute sample box, and the LPC counter is configured to estimate the count of large particles in the dilute sample box. In various embodiments, determining the by-product concentration from the runoff from the pad rinsing solution comprises collecting a sample of the runoff in a dilute sample box, diluting the collected sample in the dilute sample box with deionized water, draining excess from the deionized water and the runoff that is not collected in the dilute sample box using a drain pipe, and estimating the count of large particles in the dilute sample box using a large particle count (LPC) counter.

At step 830, process 800 heating the pad rinsing solution while continuing to rinse the polishing pad surface when the by-product concentration is above a first by-product threshold level. In various embodiments, heating the pad rinsing solution comprises generating heat from a heat source and transferring the heat from the heat source to the pad rinsing solution in a polishing pad rinsing nozzle without directly contacting the pad rinsing solution using a heat transfer structure configured to transfer heat from the heat source to the pad rinsing solution without directly contacting the pad rinsing solution.

In various embodiments, the heat transfer structure comprises a quartz structure wrapped around at least a portion of the polishing pad rinsing nozzle. In various embodiments, the heat transfer structure comprises a ceramic structure wrapped around at least a portion of the polishing pad rinsing nozzle. In various embodiments, the heat transfer structure comprises a bendable tube-like spring structure. In various embodiments, the heat transfer structure comprises a non-bendable tube-like structure.

In various embodiments, a cross-sectional slice of the heat transfer structure has a rectangular, square-like, or other polynomial shape. In various embodiments, a cross-sectional slice of the heat transfer structure has a circular shape.

In various embodiments, the heat source comprises a microwave source for applying heat to the pad rinsing solution. In various embodiments, the heat source comprises a hot plate source for applying heat to the pad rinsing solution.

In various embodiments, the method further comprises estimating pad rinsing solution temperature at or near an outlet of the polishing pad rinsing nozzle and determining how much of the heat from the heat source to apply to the pad rinsing solution based on the pad rinsing solution temperature. In various embodiments, estimating the pad rinsing solution temperature comprises estimating the pad rinsing solution temperature with a temperature measurement device. In various embodiments, the temperature measurement device comprises a valve configured to open when the pad rinsing solution temperature at or near the outlet of the polishing pad rinsing nozzle is estimated to be at or above a first temperature threshold level and configured to close when the pad rinsing solution temperature at or near the outlet of the polishing pad rinsing nozzle is estimated to be below the second temperature threshold level

In various embodiments, the first temperature threshold level is substantially higher than the second temperature threshold. In various embodiments, the first temperature threshold level is substantially equal to the second temperature threshold.

At step 840, process 800 ceasing to heat the pad rinsing solution when the by-product concentration is below a second by-product threshold level. In various embodiments, the particle by-products comprise particles greater than a predetermined size (e.g., 10 nm˜5000 nm).

At step 850, process 800 ceasing rinsing the polishing pad surface.

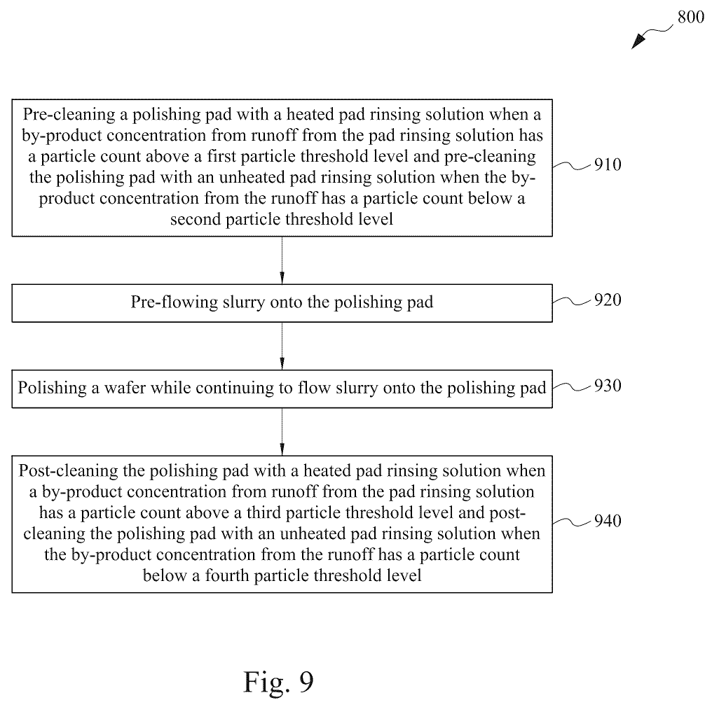

FIG. 9 is a process flow chart depicting an example process 900 for semiconductor planarization. The process 900 is merely an example, and is not intended to limit the present disclosure beyond what is explicitly recited in the claims. Additional steps may be provided before, during, and after example process 900, and some of the steps described can be moved, replaced, or eliminated for additional embodiments of example process 900.

At step 910, process 900 includes pre-cleaning the polishing pad with a heated pad rinsing solution when a by-product concentration from runoff from the pad rinsing solution has a particle count above a first particle threshold level and pre-cleaning the polishing pad with an unheated pad rinsing solution when the by-product concentration from the runoff has a particle count below a second particle threshold level. In various embodiments, the first particle threshold level is substantially higher than the second particle threshold level. In various embodiments, the first particle threshold level is substantially equal to the second particle threshold level.

At step 920, process 900 includes pre-flowing slurry onto the polishing pad, and at step 930, process 900 includes polishing a wafer while continuing to flow slurry onto the polishing pad.

At step 940, process 900 includes post-cleaning the polishing pad with a heated pad rinsing solution when a by-product concentration from runoff from the pad rinsing solution has a particle count above a third particle threshold level and post-cleaning the polishing pad with an unheated pad rinsing solution when the by-product concentration from the runoff has a particle count below a fourth particle threshold level. In various embodiments, the third particle threshold level is substantially higher than the fourth particle threshold level. In various embodiments, the third particle threshold level is substantially equal to the fourth particle threshold level.

In some aspects, the techniques described herein relate to a chemical mechanical planarization (CMP) system, including: a polishing pad including a polishing pad surface for polishing a wafer surface; and a cleaning system configured to clean the polishing pad surface using a pad rinsing solution, the cleaning system including: a heat system including a heat source for generating heat and a heat controller configured to determine when to apply the heat from the heat source to the pad rinsing solution; and a measurement system including a particle counter configured to measure a concentration of particle by-products in runoff from rinsing the polishing pad surface and a zeta potential meter configured to estimate a zeta potential of the pad rinsing solution at or near an outlet of a polishing pad rinsing nozzle; wherein the heat controller is configured to begin applying the heat from the heat source to the pad rinsing solution when the concentration of particle by-products in the runoff is above a first threshold level; and wherein the heat controller is configured to determine how much of the heat from the heat source to apply to the pad rinsing solution based on the zeta potential of the pad rinsing solution estimated from the zeta potential meter.

In some aspects, the techniques described herein relate to a CMP system, wherein the heat source further includes a microwave source or a hot plate for applying heat to the pad rinsing solution.

In some aspects, the techniques described herein relate to a CMP system, wherein the heat system further includes a heat transfer structure configured to transfer heat from the heat source to the to the pad rinsing solution and the heat transfer structure includes a quartz structure or a ceramic structure wrapped around at least a portion of the polishing pad rinsing nozzle.

In some aspects, the techniques described herein relate to a CMP system, wherein the heat transfer structure includes a bendable structure.

In some aspects, the techniques described herein relate to a CMP system, wherein the heat transfer structure includes a non-bendable structure.

In some aspects, the techniques described herein relate to a CMP system, wherein the heat controller is configured to provide a temperature command directed to the heat source based on a set temperature and a bias correction determined based on a pad rinsing solution temperature estimated from a temperature measurement device and the zeta potential of the pad rinsing solution estimated from the zeta potential meter.

In some aspects, the techniques described herein relate to a CMP system, wherein the pad rinsing solution includes a mixture of deionized water and a chemical chelator.

In some aspects, the techniques described herein relate to a CMP system, wherein the measurement system further includes a temperature measurement device configured to estimate pad rinsing solution temperature at or near an outlet of a polishing pad rinsing nozzle and wherein the heat controller is further configured to determine how much of the heat from the heat source to apply to the pad rinsing solution based on a pad rinsing solution temperature estimated from a temperature measurement device.

In some aspects, the techniques described herein relate to a semiconductor planarization method, including: commencing rinsing a polishing pad surface for polishing a wafer surface with a pad rinsing solution including deionized water and a chemical chelator configured to capture metal by-products from chemical mechanical planarization (CMP) operations; determining a by-product concentration from runoff from the pad rinsing solution; heating the pad rinsing solution while continuing to rinse the polishing pad surface when the by-product concentration is above a first by-product threshold level; ceasing to heat the pad rinsing solution when the by-product concentration is below a second by-product threshold level; and ceasing rinsing the polishing pad surface.

In some aspects, the techniques described herein relate to a method, wherein commencing rinsing the polishing pad surface is performed before the wafer surface is polished using CMP operations.

In some aspects, the techniques described herein relate to a method, wherein commencing rinsing the polishing pad surface is performed after the wafer surface is polished using CMP operations.

In some aspects, the techniques described herein relate to a method, wherein determining the by-product concentration from the runoff includes measuring the by-product concentration in the runoff using a particle counter including a drain pipe, a dilute sample box, and a large particle count (LPC) counter, wherein the dilute sample box is configured to collect at least a portion of the runoff and deionized water used to dilute the runoff, the drain pipe is provided to release excess from the deionized water and the runoff that is not collected in the dilute sample box, and the LPC counter is configured to estimate a count of particles greater than a predetermined particle size in the dilute sample box.

In some aspects, the techniques described herein relate to a method, wherein heating the pad rinsing solution includes transferring heat from a heat source to the pad rinsing solution in a polishing pad rinsing nozzle without directly contacting the pad rinsing solution.

In some aspects, the techniques described herein relate to a method, further including estimating pad rinsing solution temperature at or near an outlet of a polishing pad rinsing nozzle and determining how much heat from a heat source to apply to the pad rinsing solution based on the pad rinsing solution temperature.

In some aspects, the techniques described herein relate to a method, wherein determining the by-product concentration from the runoff from the pad rinsing solution includes collecting a sample of the runoff in a dilute sample box, diluting the collected sample in the dilute sample box with deionized water, draining excess from the deionized water and the runoff that is not collected in the dilute sample box using a drain pipe, and estimating a count of particles greater than a predetermined particle size.

In some aspects, the techniques described herein relate to a chemical mechanical planarization (CMP) system, including: a polishing pad including a polishing pad surface for polishing a wafer surface; a polishing pad rinsing nozzle for selectively providing a pad rinsing solution for rinsing the polishing pad; and a cleaning system configured to clean the polishing pad surface using the pad rinsing solution, the cleaning system including: a heat source for generating heat; a heat transfer structure configured to transfer heat from the heat source to the pad rinsing solution in the polishing pad rinsing nozzle without directly contacting the pad rinsing solution; a measurement system including a particle counter configured to measure a concentration of particle by-products in runoff from rinsing the polishing pad surface; and a heat controller configured to determine when to apply the heat from the heat source to the pad rinsing solution, wherein the heat controller is configured to begin applying the heat from the heat source to the pad rinsing solution when the concentration of particle by-products in the runoff is above a first particle threshold level.

In some aspects, the techniques described herein relate to a CMP system, wherein the heat transfer structure includes a quartz structure or a ceramic structure wrapped around at least a portion of the polishing pad rinsing nozzle.

In some aspects, the techniques described herein relate to a CMP system, further including a zeta potential meter configured to estimate zeta potential of the pad rinsing solution at or near an outlet of the polishing pad rinsing nozzle, and wherein the heat controller is configured to determine how much of the heat from the heat source to apply to the pad rinsing solution based on the zeta potential of the pad rinsing solution estimated from the zeta potential meter.

In some aspects, the techniques described herein relate to a CMP system, wherein the heat controller includes one or more processors configured by programming instructions to determine how much of the heat from the heat source to apply to the pad rinsing solution based on the zeta potential of the pad rinsing solution estimated from the zeta potential meter.

In some aspects, the techniques described herein relate to a CMP system, wherein the heat controller is configured to cease applying heat from the heat source when the concentration of particle by-products in the runoff is below a second particle threshold level.

In some aspects, the techniques described herein relate to a CMP system, wherein the first particle threshold level is substantially higher than the second particle threshold level.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A chemical mechanical planarization (CMP) system, comprising:
a polishing pad comprising a polishing pad surface for polishing a wafer surface; and
a cleaning system configured to clean the polishing pad surface using a pad rinsing solution, the cleaning system comprising:
a heat system comprising a heat source for generating heat and a heat controller configured to determine when to apply the heat from the heat source to the pad rinsing solution; and
a measurement system comprising a particle counter configured to measure a concentration of particle by-products in runoff from rinsing the polishing pad surface and a zeta potential meter configured to estimate zeta potential of the pad rinsing solution at or near an outlet of a polishing pad rinsing nozzle;
wherein the heat controller is configured to begin applying the heat from the heat source to the pad rinsing solution when the concentration of particle by-products in the runoff is above a first threshold level; and
wherein the heat controller is configured to determine how much of the heat from the heat source to apply to the pad rinsing solution based on the zeta potential of the pad rinsing solution estimated from the zeta potential meter.

2. The CMP system of claim 1, wherein the heat source further comprises a microwave source or a hot plate for applying heat to the pad rinsing solution.

3. The CMP system of claim 1, wherein the heat system further comprises a heat transfer structure configured to transfer heat from the heat source to the to the pad rinsing solution and the heat transfer structure comprises a quartz structure or a ceramic structure wrapped around at least a portion of the polishing pad rinsing nozzle.

4. The CMP system of claim 3, wherein the heat transfer structure comprises a bendable structure.

5. The CMP system of claim 1, wherein the heat controller is configured to provide a temperature command directed to the heat source based on a set temperature and a bias correction determined based on a pad rinsing solution temperature estimated from a temperature measurement device and the zeta potential of the pad rinsing solution estimated from the zeta potential meter.

6. The CMP system of claim 1, wherein the pad rinsing solution comprises a mixture of deionized water and a chemical chelator.

7. The CMP system of claim 1, wherein the measurement system further comprises a temperature measurement device configured to estimate pad rinsing solution temperature at or near an outlet of a polishing pad rinsing nozzle and wherein the heat controller is further configured to determine how much of the heat from the heat source to apply to the pad rinsing solution based on a pad rinsing solution temperature estimated from a temperature measurement device.

8. A semiconductor planarization method, comprising:
commencing rinsing a polishing pad surface for polishing a wafer surface with a pad rinsing solution comprising deionized water and a chemical chelator configured to capture metal by-products from chemical mechanical planarization (CMP) operations;
determining a by-product concentration from runoff from the pad rinsing solution;
heating the pad rinsing solution while continuing to rinse the polishing pad surface when the by-product concentration is above a first by-product threshold level;
ceasing to heat the pad rinsing solution when the by-product concentration is below a second by-product threshold level; and
ceasing rinsing the polishing pad surface.

9. The method of claim 8, wherein commencing rinsing the polishing pad surface is performed before the wafer surface is polished using CMP operations.

10. The method of claim 8, wherein commencing rinsing the polishing pad surface is performed after the wafer surface is polished using CMP operations.

11. The method of claim 8, wherein determining the by-product concentration from the runoff comprises measuring the by-product concentration in the runoff using a particle counter comprising a drain pipe, a dilute sample box, and a large particle count (LPC) counter, wherein the dilute sample box is configured to collect at least a portion of the runoff and deionized water used to dilute the runoff, the drain pipe is provided to release excess from the deionized water and the runoff that is not collected in the dilute sample box, and the LPC counter is configured to estimate a count of particles greater than a predetermined particle size in the dilute sample box.

12. The method of claim 8, wherein heating the pad rinsing solution comprises transferring heat from a heat source to the pad rinsing solution in a polishing pad rinsing nozzle without directly contacting the pad rinsing solution.

13. The method of claim 8, further comprising estimating pad rinsing solution temperature at or near an outlet of a polishing pad rinsing nozzle and determining how much heat from a heat source to apply to the pad rinsing solution based on the pad rinsing solution temperature.

14. The method of claim 8, wherein determining the by-product concentration from the runoff from the pad rinsing solution comprises collecting a sample of the runoff in a dilute sample box, diluting the collected sample in the dilute sample box with deionized water, draining excess from the deionized water and the runoff that is not collected in the dilute sample box using a drain pipe, and estimating a count of particles greater than a predetermined particle size.

15. A chemical mechanical planarization (CMP) system, comprising:
a polishing pad comprising a polishing pad surface for polishing a wafer surface;
a polishing pad rinsing nozzle for selectively providing a pad rinsing solution for rinsing the polishing pad; and
a cleaning system configured to clean the polishing pad surface using the pad rinsing solution, the cleaning system comprising:
a heat source for generating heat;
a heat transfer structure configured to transfer heat from the heat source to the pad rinsing solution in the polishing pad rinsing nozzle without directly contacting the pad rinsing solution;
a measurement system comprising a particle counter configured to measure a concentration of particle by-products in runoff from rinsing the polishing pad surface; and
a heat controller configured to determine when to apply the heat from the heat source to the pad rinsing solution, wherein the heat controller is configured to begin applying the heat from the heat source to the pad rinsing solution when the concentration of particle by-products in the runoff is above a first particle threshold level.

16. The CMP system of claim 15, wherein the heat transfer structure comprises a quartz structure or a ceramic structure wrapped around at least a portion of the polishing pad rinsing nozzle.

17. The CMP system of claim 15, further comprising a zeta potential meter configured to estimate zeta potential of the pad rinsing solution at or near an outlet of the polishing pad rinsing nozzle, and wherein the heat controller is configured to determine how much of the heat from the heat source to apply to the pad rinsing solution based on the zeta potential of the pad rinsing solution estimated from the zeta potential meter.

18. The CMP system of claim 15, wherein the heat controller comprises one or more processors configured by programming instructions to determine how much of the heat from the heat source to apply to the pad rinsing solution based on a zeta potential measurement of the pad rinsing solution from a zeta potential meter.

19. The CMP system of claim 15, wherein the heat controller is configured to cease applying heat from the heat source when the concentration of particle by-products in the runoff is below a second particle threshold level.

20. The CMP system of claim 19, wherein the first particle threshold level is substantially higher than the second particle threshold level.
